(19) United States
(12) Patent Application Publication
(10) Pub. No.: US 2025/0176360 A1
(43) Pub. Date: May 29, 2025

(54) DISPLAY DEVICE AND METHOD FOR MANUFACTURING THE SAME

(71) Applicant: LG Display Co., Ltd., Seoul (KR)

(72) Inventor: Jeong-Min PARK, Paju-si (KR)

(21) Appl. No.: 18/522,636

(22) Filed: Nov. 29, 2023

(51) Int. Cl. H10K 59/122; H10K 59/40

(52) U.S. Cl. CPC H10K 59/122; H10K 59/40

(57) ABSTRACT

A display device and a method for manufacturing the same. The display device may include: a substrate having first and second subpixels each including a respective emitting area and a non-emitting area surrounding the emitting areas; a respective first electrode in each of the first and second subpixels; a bank, the bank having a respective bank hole in each of the emitting areas and a bank trench in the non-emitting area; a first spacer on the bank; a second spacer in the bank trench; an emitting layer on the first electrode and the bank trench and including a plurality of stacks and at least one charge generating layer between the plurality of stacks; and a second electrode on the emitting layer.

### BACKGROUND

### Technical Field

The present disclosure relates to a display device such as a light emitting diode display device and a method for manufacturing the same, and more particularly, to a display device (such as a light emitting diode display device) having a structure for reducing or preventing a leakage current between adjacent subpixels and a method for manufacturing the same.

### Description of the Related Art

A recent display device displaying an information and interacting with a user watching the information is required to have various sizes, various shapes and various functions.

The display device may include a liquid crystal display (LCD) device, an electrophoretic display (EPD) device and a light emitting diode (LED) display device.

The LED display device has an emissive type and may be fabricated to have a light weight and a thin profile because an additional light source is not required differently from the LCD device. Further, the LED display device has an advantage in a power consumption due to a low voltage driving and has a superiority in a color display, a response speed, a viewing angle and a contrast ratio. As a result, the LED display device has been researched as a next generation display.

The LED display device displays the information by lighting a plurality of pixels having the emitting layer. The LED display device may be classified into an active matrix type LED display device and a passive matrix type LED display device according to a method of driving the pixels.

The active matrix type LED display device displays an image by controlling a current flowing through a light emitting diode using a thin film transistor (TFT).

The LED display device has an anode, an emitting layer and a cathode. When a voltage is applied to the anode and the cathode, a hole of the anode and an electron of the cathode move to the emitting layer. The hole and the electron are combined in the emitting layer to generate an exciton, and a light is emitted when the exciton transitions from an excited state to a ground state.

### BRIEF SUMMARY

To provide an image information of a high quality, a resolution of the LED display device gradually increases. As the resolution increases, a gap distance between adjacent subpixels is reduced. As a result, the image information is distorted due to a leakage current along a lateral direction between the adjacent subpixels.

Embodiments of the present disclosure are directed to a light emitting diode display device that substantially obviate one or more of problems due to the limitations and disadvantages of the related art.

The present disclosure provides a light emitting display device having a bank trench including at least one second spacer between adjacent subpixels, which reduces or prevents a lateral leakage current that generally increases as a gap distance between the adjacent subpixels decreases.

Additional features and technical benefits of the disclosure will be set forth in the description herein, and in part will be apparent to those skilled in the art from the description or may be learned by practice of the disclosure. These and other technical benefits of the disclosure may be realized and attained by the structure particularly pointed out in, or derivable from, the written description, claims hereof, and the appended drawings.

As embodied and broadly described herein, a display device may include: a substrate having first and second subpixels each including a respective emitting area and a non-emitting area surrounding the emitting areas; a respective first electrode in each of the first and second subpixels; a bank, the bank having a respective bank hole in each of the emitting areas and a bank trench in the non-emitting area; a first spacer on the bank; a second spacer in the bank trench; an emitting layer on the first electrode and the bank trench and including a plurality of stacks and at least one charge generating layer between the plurality of stacks; and a second electrode on the emitting layer.

In another aspect of the present disclosure, a display device may include: a substrate including a display area having a plurality of subpixels and a non-emitting area between the plurality of subpixels and a non-display area adjacent to the display area; a respective first electrode in each of the plurality of subpixels; a bank dividing the plurality of subpixels; an emitting layer on the first electrodes; a second electrode on the emitting layer; and a cut in the emitting layer between two adjacent subpixels of the plurality of subpixels.

According to still another example embodiment of the present disclosure, a method for manufacturing a display device may include: forming a plurality of first electrodes spaced apart from each other on a substrate; forming a bank on the substrate on which the plurality of first electrodes are formed; forming a bank hole in the bank so that a portion of each of the plurality of first electrodes is exposed, and forming a bank trench between adjacent first electrodes of the plurality of first electrodes in the bank; forming a second spacer in the bank trench; forming an emission layer on the second spacer and the bank trench, the emission layer including a plurality of stacks and at least one charge generating layer between the plurality of stacks; and forming a second electrode on the emission layer.

Although an organic light emitting diode (OLED) display device is used to illustrate an LED display device, an LED display device may include other materials for the light emitting layer, and a material of an emitting layer is not limited thereto.

It is to be understood that both the foregoing general description and the following detailed description are explanatory and by way of examples and are intended to provide further explanation of the disclosure without limiting its scope.

### BRIEF DESCRIPTION OF THE SEVERAL VIEWS OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a plan view showing a light emitting diode display device according to an embodiment of the present disclosure;

FIG. 2 is a plan view showing a subpixel and a bank trench having a second spacer of a light emitting diode display device according to an embodiment of the present disclosure;

FIG. 3 is a cross-sectional view showing a light emitting diode display device according to an embodiment of the present disclosure;

FIGS. 4A to 4D are cross-sectional views showing a fabrication process of a light emitting diode display device according to an embodiment of the present disclosure; and

FIG. 5 is view showing an emitting layer of a light emitting diode display device according to an embodiment of the present disclosure.

### DETAILED DESCRIPTION

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. Like reference numerals refer to like elements throughout, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

Features of various embodiments of the present disclosure may be partially or entirely coupled to or combined with each other. They may be linked and operated technically in various ways as those skilled in the art can sufficiently understand. The embodiments may be carried out independently of or in association with each other in various combinations.

Hereinafter, a light emitting diode display device according to various example embodiments of the present disclosure will be described in detail with reference to the accompanying drawings.

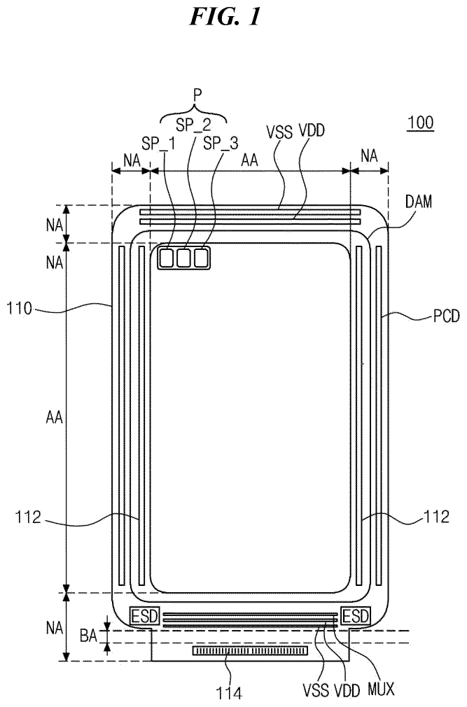

FIG. 1 is a plan view showing a light emitting diode display device according to an embodiment of the present disclosure.

In FIG. 1, a light emitting diode (LED) display device 100 according to an embodiment of the present disclosure may include various elements for generating signals or driving a plurality of subpixels SP_1, SP_2 and SP_3 in a display area AA. For example, the LED display device 100 may include at least one driving circuit for controlling a display panel. A driving circuit for controlling or driving the subpixels SP_1, SP_2 and SP_3 may include a gate driving unit 112, data signal lines, a multiplexer MUX, an electrostatic discharge circuit ESD, a high level voltage line VDD, a low level voltage line VSS and an inverter circuit. The LED display device 100 may further include elements other than the elements for driving the subpixels SP_1, SP_2 and SP_3. For example, the LED display device 100 may include elements providing a touch sensing function, a user authentication function (e.g., fingerprint recognition), a multilevel pressure sensing function and a tactile feedback. The elements may be disposed in a non-display area NA or an external circuit connected to a connection interface.

A substrate 110 may include a display area AA and a non-display area NA. In the display area AA of the substrate 110, a plurality of pixels P are disposed and an image is displayed. In the non-display area NA of the substrate 110, an image is not displayed. For example, the non-display area NA may be referred to as a bezel area, and it is not limited thereto. The non-display area NA may be disposed adjacent to the display area AA and may be disposed outer than the display area AA. Alternatively, the non-display area NA may be disposed to surround a whole or a part of the display area AA. The non-display area NA may be a region where the plurality of subpixels SP_1, SP_2 and SP_3 are not disposed, and it is not limited thereto.

Each pixel P in the display area AA may include the plurality of subpixels SP_1, SP_2 and SP_3. Each subpixel SP_1, SP_2 and SP_3 is an individual unit emitting a light. The plurality of subpixels SP_1, SP_2 and SP_3 may include a red subpixel SP_R, a green subpixel SP_G and a blue subpixel SP_B and/or a white subpixel, and it is not limited thereto.

Each subpixel SP_1, SP_2 and SP_3 includes a light emitting diode and a subpixel circuit. For example, each subpixel SP_1, SP_2 and SP_3 may include a light emitting diode for displaying an image and a subpixel circuit for driving or controlling the light emitting diode.

Each subpixel SP may include a plurality of transistors, one or a plurality of capacitors and a plurality of lines. For example, each subpixel SP may have a 2T1C structure including two transistors and one capacitor. Alternatively, each subpixel SP may have one of 3T1C, 4T1C, 5T1C, 6TIC, 7T1C, 3T2C, 4T2C, 5T2C, 6T2C, 7T2C and 8T2C structures.

The non-display area NA is a region where a plurality of lines and a plurality of driving circuits for driving the plurality of subpixels SP_1, SP_2 and SP_3 of the display area AA are disposed. For example, a plurality of integrated circuits (ICs) and a driving circuit such as the gate driving unit 112 and a data driving unit may be disposed in the non-display area NA.

Although the non-display area NA surrounds the display area AA of a rectangular shape in FIG. 1, a shape and a disposition of the display area AA and the non-display area NA adjacent to each other are not limited thereto. The display area AA and the non-display area NA may have a shape corresponding to a design of an electronic equipment having the LED display device 100. The display area AA and the non-display area NA may have a circular shape corresponding to a wrist watch for a wearable device and may have a free form for a dashboard. For example, the display area AA may have one of pentagonal, hexagonal, octagonal, circular and elliptical shapes, and it is not limited thereto.

The non-display area NA may include a bending area BA. The bending area BA may be disposed between the display area AA and a pad part 114 of the non-display area NA. The bending area BA may be a region where a connecting line part is disposed.

The bending area BA may be a region where a portion of the substrate 110 is bent to dispose the pad part 114 and an external module bonded to the pad part 114 over a rear surface of the substrate 110. For example, since the bending area BA is bent toward the rear surface of the substrate 110, the external module bonded to the pad part 114 of the substrate 110 moves toward the rear surface of the substrate 110 and is not recognized in a plan view of the substrate 110. While FIG. 1 may show the display device 100 in plan view before bending of the bending area BA, such that the pad part 114 is visible in FIG. 1, after bending of the bending area BA, the pad part 114 may be disposed on a rear side of the display device 100 such that it is no longer visible from the front side of the display device 100. Further, since the bending area BA is bent, a size of the non-display area NA is reduced in a plan view of a user, a narrow bezel is obtained. Although the bending area BA is disposed in the non-display area NA in the LED display device 100, it is not limited thereto. For example, the bending area BA may be disposed in the display area AA, and the display area AA may be bent toward various directions such that the bending area BA of the display area AA have similar effects to the bending area BA of the non-display area NA.

The pad part 114 is disposed in one side of the non-display area NA. The pad part 114 is a metallic pattern where the external module such as flexible printed circuit board (FPCB) and a chip on film (COF) is bonded. Although the pad part 114 is disposed adjacent to one side of the substrate 110, a shape and a disposition of the pad part 114 is not limited thereto.

The gate driving unit 112 providing a gate signal to a thin film transistor (TFT) may be disposed in another side of the non-display area NA. The gate driving unit 112 may include a plurality of gate driving circuits, and the plurality of gate driving circuits may be formed directly on the substrate 110. For example, the gate driving unit 112 formed directly on the substrate 110 may have a gate-in-panel (GIP) type.

The gate driving unit 112 may be disposed between the display area AA and a dam DAM of the non-display area NA.

The high level voltage line VDD, the low level voltage line VSS, the multiplexer MUX, the electrostatic discharge circuit ESD and the plurality of connecting line parts may be disposed between the display area AA and the pad part 114 of the non-display area NA.

The high level voltage line VDD, the low level voltage line VSS, the multiplexer MUX and the electrostatic discharge circuit ESD may be disposed between the display area AA and the bending area BA.

The plurality of connecting line parts may be disposed in the non-display area NA. For example, the plurality of connecting line parts may be disposed in the bending area BA of the non-display area NA where the substrate 110 is bent. The plurality of connecting line parts may be a structure for transmitting signals (voltages) of the external module bonded to the pad part 114 to the display area AA or a circuit unit such as a gate driving unit 112. For example, a plurality of signals such as signals for driving the gate driving unit 112, a data signal, a high level voltage and a low level voltage may be transmitted through the plurality of connecting line parts.

The dam DAM is disposed in the non-display area NA to surround a whole or a portion of the display area AA. The dam DAM may be disposed adjacent to the display area AA and may be disposed outside the display area AA.

The dam DAM may be disposed at a periphery of the display area AA to adjust a flow of an organic material for a second encapsulating layer on the light emitting diode. The dam DAM may be disposed as one or more.

The dam DAM may be disposed among the display area AA, the high level voltage line VDD, the low level voltage line VSS, the multiplexer MUX and the electrostatic discharge circuit ESD.

A crack detecting line PCD may be disposed in the non-display area NA of the substrate 110.

The crack detecting line PCD may be disposed between an end portion of the substrate 110 and the dam DAM. Alternatively, the crack detecting line PCD may be disposed under the dam DAM to overlap the dam DAM partially.

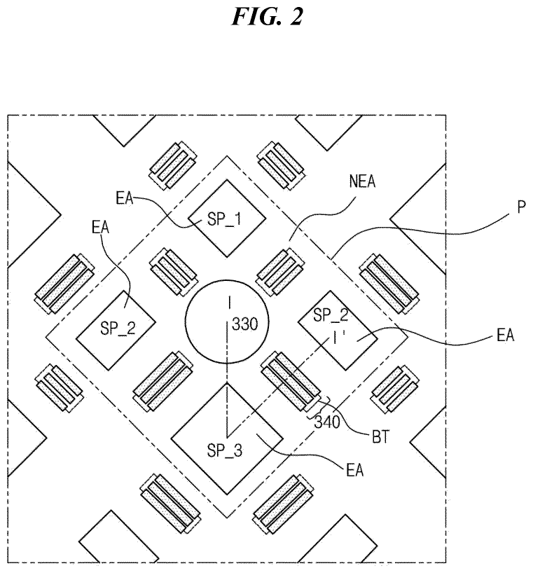

FIG. 2 is a plan view showing a subpixel and a bank trench having a second spacer of a light emitting diode display device according to an embodiment of the present disclosure.

In FIG. 2, the substrate 110 may include an emitting area EA and a non-emitting area NEA surrounding the emitting area EA. The emitting area EA may be disposed as plurals spaced apart from each other. The non-emitting area NEA may be disposed to surround the emitting area EA.

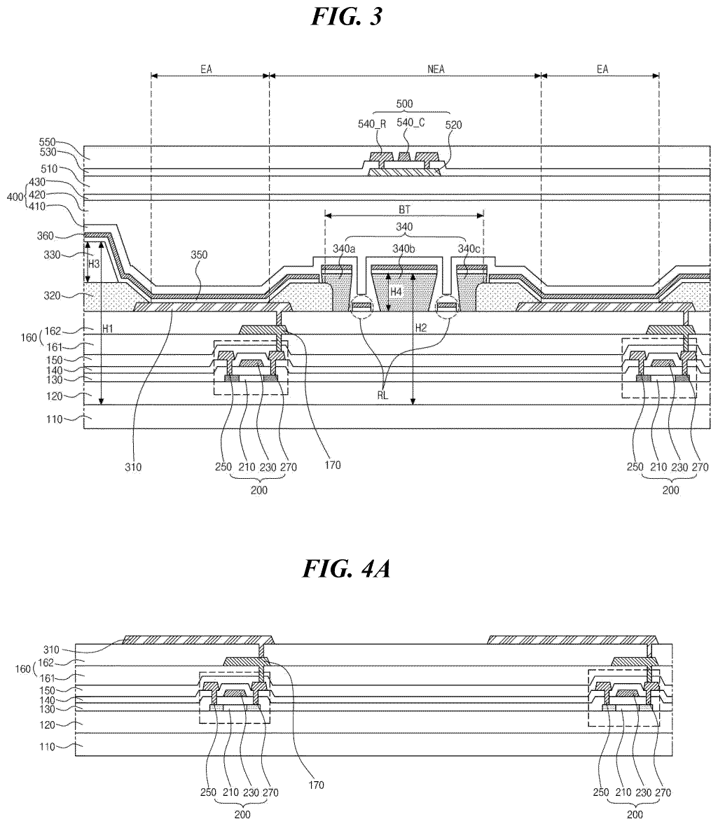

The emitting area EA is a region where a light is emitted to an exterior. As shown in FIG. 3, the emitting area EA may be a region where a bank 320 is not disposed.

The non-emitting area NEA is a region where a light is not emitted to an exterior. As shown in FIG. 3, the non-emitting area NEA may be a region where a bank 320 is disposed.

Each of the plurality of pixels P of the display area AA may include first, second and third subpixels SP_1, SP_2 and SP_3.

Each of the first, second and third subpixels SP_1, SP_2 and SP_3 may include the emitting area EA.

Each pixel P may include one subpixel emitting a light corresponding to a different color. For example, each pixel P may include one first subpixel SP_1, one second subpixel SP_2 and one third subpixel SP_3 corresponding to different colors.

Alternatively or additionally, each pixel P may include a plurality of subpixels emitting a light corresponding to a different color. For example, each pixel P may include one first subpixel SP_1, two second subpixels SP_2 and one third subpixel SP_3 corresponding to different colors.

The first, second and third subpixels SP_1, SP_2 and SP_3 may have one of rectangular, pentagonal, hexagonal, octagonal, circular and elliptical shapes, or other shapes, and it is not limited thereto.

The first, second and third subpixels SP_1, SP_2 and SP_3 may emit a light corresponding to a different color. For example, the first, second and third subpixels SP_1, SP_2 and SP_3 may emit a light corresponding to at least one of red, green and blue colors.

The third subpixel SP_3 may have a size greater than the first and second subpixels SP_1 and SP_2. As shown in FIG. 2, the third subpixel SP_3 may be greater than the first subpixel SP_1 and greater than the second subpixel SP_2.

In the light emitting diode display device, as a resolution increases, a gap distance between the first, second and third subpixels SP_1, SP_2 and SP_3 is reduced.

The LED display device 100 may have an emitting layer including a plurality of stacks (emitting units) and a charge generating layer between the plurality of stacks. The charge generating layer may adjust a charge balance between the plurality of stacks.

The charge generating layer may have a plurality of layers including first and second charge generating layers. Each of the first and second charge generating layers may have a negative type charge generating layer and a positive type charge generating layer. The first charge generating layer may include an alkali metal such as lithium (Li), sodium (Na), potassium (K) and cesium (Cs) or an organic layer doped with one of magnesium (Mg), strontium (Sr), barium (Ba) and radium (Ra).

A metal in the charge generating layer may cause a lateral leakage current (LLC). For example, when the subpixel is driven, the adjacent subpixels may emit a weak light due to a leakage current along a lateral direction between the adjacent subpixels and the image information may be distorted.

The first, second and third subpixels SP_1, SP_2 and SP_3 may have different driving voltages for emitting a light.

For example, the driving voltage for emitting a blue colored light may be greater than the driving voltage for emitting a red colored light or a green colored light.

When the third subpixel SP_3 is driven, the adjacent subpixels may be driven to emit a weak light. An electron of the third subpixel SP_3 is transmitted to the adjacent subpixels through the charge generating layer continuously disposed between the adjacent subpixels. As a result, the third subpixel SP_3 may have a similar state to the adjacent subpixels having an off state and may emit a weak light. Accordingly, a color purity is reduced and a color reproducibility is reduced. Specifically, the weak light may occur in a relatively low gray level.

The lateral leakage current may be reduced or minimized by a bank trench BT having a second spacer 340 being disposed between the adjacent subpixels in the non-emitting area NEA.

Although the second spacers 340 are disposed to surround each of the first, second and third subpixels SP_1, SP_2 and SP_3 in FIG. 2, the second spacers 340 may be disposed to surround some of the first, second and third subpixels SP_1, SP_2 and SP_3 in another embodiment. In some examples, the second spacers 340 may be disposed to surround the third subpixels SP_3 configured to emit blue light only. Since these subpixels have the highest driving voltage, there is more risk of leakage current from these subpixels to adjacent subpixels.

The emitting layer 350 is disposed on a first electrode 310 and the bank trench BT having the second spacer 340. Since the emitting layer 350 between the adjacent subpixels is cut by the bank trench BT having the second spacer 340 in some example embodiments, it is minimized that the electron in the emitting layer 350 of the subpixel is transmitted to the adjacent subpixel.

Since the lateral leakage current is reduced or minimized between the adjacent subpixels, a recognition deterioration between the adjacent subpixels in a relatively low gray level is reduced and a color reproducibility is improved.

Although the second spacer 340 and the bank trench BT are disposed among the first, second and third subpixels SP_1, SP_2 and SP_3 in FIG. 2, the second spacer 340 and the bank trench BT may be omitted between adjacent subpixels in another embodiment. In other words, respective instances of the second spacer 340 and the bank trench BT may be disposed between one adjacent pair of the subpixels or between multiple adjacent pairs of the subpixels or between all adjacent pairs of the subpixels.

A first spacer 330 may be disposed to have a predetermined gap distance with the plurality of subpixels SP_1, SP_2 and SP_3. For example, the first spacer 330 may have a gap distance with the plurality of subpixels SP_1, SP_2 and SP_3 and may be surrounded by the plurality of subpixels SP_1, SP_2 and SP_3. Although one first spacer 330 is surrounded by four subpixels SP_1, SP_2 and SP_3 in FIG. 2, it is not limited thereto. The first spacer 330 may provide a gap between the subpixels SP_1, SP_2, SP_3 and may be separated from the subpixels SP_1, SP_2, SP_3 by respective gaps. As used herein, the first spacer 330 may be referred to as an on-bank spacer and the second spacer 340 may be referred to as an in-bank spacer. It will be appreciated that ‘first’ and ‘second’ are used merely as labels for referring to the spacers and should not be considered to be limiting.

The subpixels emitting the same colored light may be symmetrically disposed with respect to the first spacer 330. For example, the second subpixels SP_2 may be disposed to face into each other with respect to the first spacer 330. The first spacer 330 may be disposed at a central region of the subpixels emitting the same colored light.

The first spacer 330 may alleviate a space between the substrate 110 having an emitting layer 350 and an upper substrate (an encapsulating layer 400) to minimize a break of the LED display device 100 due to an impact from the exterior.

Further, the first spacer 330 may protect the emitting layer 350. For example, the emitting layer 350 may be formed using a fine metal mask (FMM) and the fine metal mask may be warped due to a weight. Since the fine metal mask contacts the first spacer 330, deterioration or distortion of the bank 320 due to contact of the fine metal mask and the bank 320 is prevented.

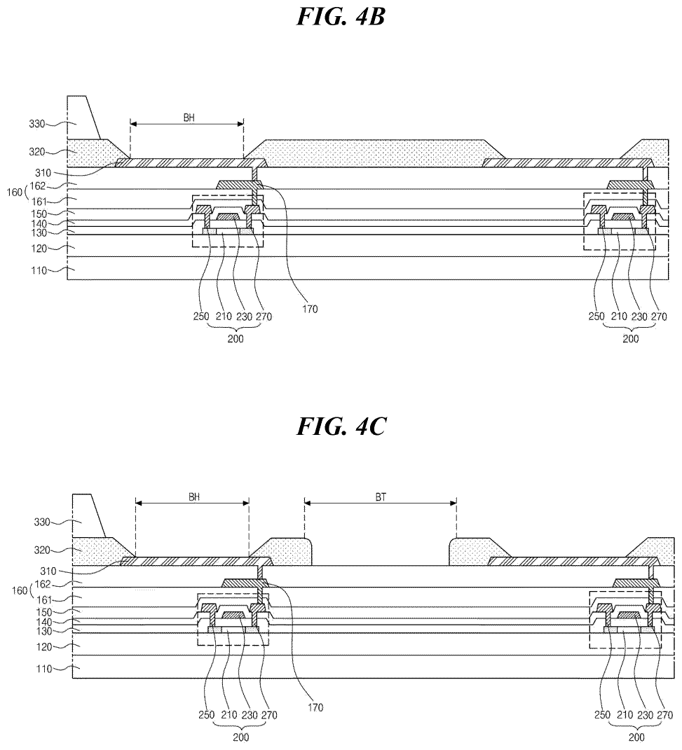

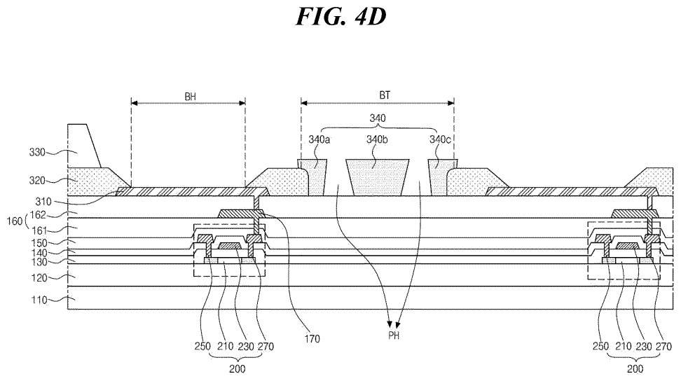

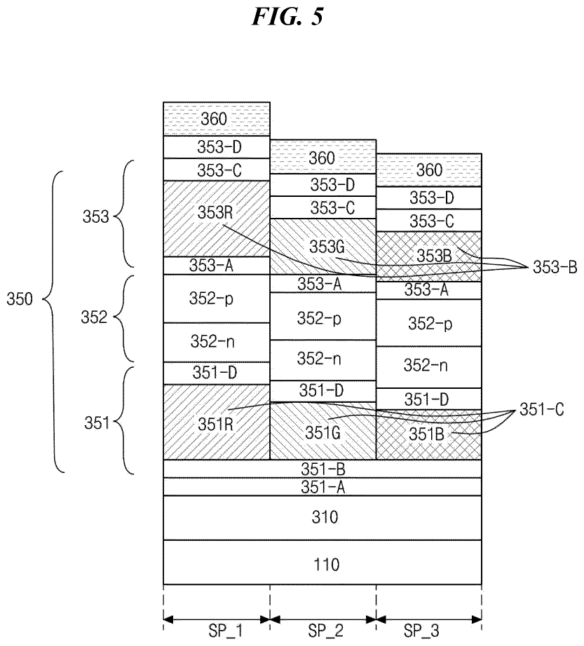

FIG. 3 is a cross-sectional view showing a light emitting diode display device according to an embodiment of the present disclosure, and FIGS. 4A to 4D are cross-sectional views showing a fabrication process of a light emitting diode display device according to an embodiment of the present disclosure. FIG. 3 is taken along a line I-I′ of FIG. 2.

In FIG. 3, the substrate 110 supports various elements of the LED display device 100. The substrate 110 may include a glass or a plastic material having a flexibility.

For example, the substrate 110 may include one of polyimide (PI), polymethylmethacrylate (PMMA), polyethylene terephthalate (PET), polyethersulfone and polycarbonate, and it is not limited thereto.

When the substrate 110 includes polyimide (PI), the substrate 110 may include two PI layers or two PI layers and an inorganic layer between the two PI layers.

A buffer layer 120 is disposed on a whole of the substrate 110.

The buffer layer 120 may include an inorganic insulating material such as silicon nitride (SiNx) and silicon oxide (SiOx). The buffer layer 120 may include an organic insulating material, and it is not limited thereto.

The buffer layer 120 may have a single layer or a multiple layer of silicon nitride (SiNx) and silicon oxide (SiOx). When the buffer layer 120 has a multiple layer, a layer of silicon oxide (SiOx) and a layer of silicon nitride (SiNx) may be alternately disposed.

The buffer layer 120 may be omitted according to a kind and a material of the substrate 110 and a structure and a type of a thin film transistor.

A thin film transistor 200 may be disposed on the buffer layer 120. The thin film transistor 200 may include a semiconductor pattern, a gate electrode, a source electrode and a drain electrode.

Although a driving thin film transistor is shown as the thin film transistor 200 in FIGS. 3 and 4A to 4D, the LED display device 100 may further include another thin film transistor such as a switching thin film transistor. Although the thin film transistor 200 has a top gate structure in FIGS. 3 and 4A to 4D, the thin film transistor may have another structure such as a bottom gate structure.

A semiconductor pattern 210 of the thin film transistor 200 is disposed on the buffer layer 120.

The semiconductor pattern 210 may include a polycrystalline semiconductor material. For example, the polycrystalline semiconductor material may include low temperature polycrystalline silicon, and it is not limited thereto. When the semiconductor pattern 210 includes a polycrystalline semiconductor material, a power consumption is reduced and a reliability is improved.

The semiconductor pattern 210 may include an oxide semiconductor material. For example, the oxide semiconductor material may include one of indium gallium zinc oxide (IGZO), indium zinc oxide (IZO), indium gallium tin oxide (IGTO) and indium gallium oxide (IGO), and it is not limited thereto. When the semiconductor pattern 210 includes an oxide semiconductor material, an effect blocking a leakage current is improved and a luminance change of the subpixel is minimized in a low frequency driving.

When the semiconductor pattern 210 includes a polycrystalline semiconductor material or an oxide semiconductor material, a portion of the semiconductor pattern 210 may include a conductive region.

The semiconductor pattern 210 may include amorphous silicon (a-Si) or an organic semiconductor material such as pentacene, and it is not limited thereto.

A first insulating layer 130 is disposed on the semiconductor pattern 210.

The first insulating layer 130 may be disposed between the semiconductor pattern 210 and a gate electrode 230 to insulate the semiconductor pattern 210 and the gate electrode 230.

The first insulating layer 130 may include an inorganic insulating material such as silicon nitride (SiNx) and silicon oxide (SiOx). The first insulating layer 130 may include an organic insulating material, and it is not limited thereto.

The first insulating layer 130 may have contact holes to electrically connect a source electrode 250 and a drain electrode 270 with the semiconductor pattern 210.

A gate electrode 230 of the thin film transistor 200 is disposed on the first insulating layer 130 to overlap the semiconductor pattern 210.

The gate electrode 230 may include one of molybdenum (Mo), copper (Cu), titanium (Ti), aluminum (Al), chromium (Cr), gold (Au), nickel (Ni), neodymium (Nd), tungsten (W) and transparent conductive oxide (TCO) or an alloy thereof and may have a single layer or a multiple layer thereof. However, it is not limited thereto.

A second insulating layer 140 is disposed on the gate electrode 230.

The second insulating layer 140 is disposed between the gate electrode 230 and the source electrode 250 and between the gate electrode 230 and the drain electrode 270 to insulate the gate electrode 230 and the source and drain electrodes 250 and 270.

The second insulating layer 140 may include an inorganic insulating material such as silicon nitride (SiNx) and silicon oxide (SiOx). The second insulating layer 140 may include an organic insulating material, and it is not limited thereto.

The second insulating layer 140 may have contact holes to electrically connect the source electrode 250 and the drain electrode 270 with the semiconductor pattern 210.

A source electrode 250 and a drain electrode 270 are disposed on the second insulating layer 140.

The source electrode 250 and the drain electrode 270 may be connected to the semiconductor pattern 210 through the contact holes in the first and second insulating layers 130 and 140.

The source electrode 250 and the drain electrode 270 may include one of molybdenum (Mo), copper (Cu), titanium (Ti), aluminum (Al), chromium (Cr), gold (Au), nickel (Ni), neodymium (Nd), tungsten (W) and transparent conductive oxide (TCO) or an alloy thereof and may have a single layer or a multiple layer thereof. However, it is not limited thereto.

For example, the source electrode 250 and the drain electrode 270 may have a triple layers of titanium (Ti)/aluminum (Al)/titanium (Ti), and it is not limited thereto.

A passivation layer 150 is disposed on the source electrode 250 and the drain electrode 270.

The passivation layer 150 may protect the thin film transistor 200. The passivation layer 150 may include an inorganic insulating material such as silicon nitride (SiNx) and silicon oxide (SiOx). The passivation layer 150 may include an organic insulating material, and it is not limited thereto.

The passivation layer 150 may have a contact hole to electrically connect the thin film transistor 200 and a connecting electrode 170.

The passivation layer 150 may be omitted according to a structure and a type of the thin film transistor 200.

A planarizing layer 160 may be disposed on the passivation layer 150 or the thin film transistor 200.

The planarizing layer 160 may protect the thin film transistor 200 and may alleviate or planarize a step difference due to various patterns.

The planarizing layer 160 may include an organic insulating material such as benzocyclobutene (BCB), acrylic resin, epoxy resin, phenolic resin, polyamide resin and polyimide resin, and it is not limited thereto.

The planarizing layer 160 may have a single layer or a multiple layer based on disposition of electrodes.

In the LED display device 100, since a number of signal lines increases as a resolution increases, the signal lines may not be formed as a single layer with a predetermined gap distance. As a result, the signal lines may have a multiple layer for a sufficient margin. Further, when the planarizing layer 160 has a multiple layer of a dielectric material, the planarizing layer 160 may be used for a capacitor between metal layers.

The planarizing layer 160 may include a first planarizing layer 161 and a second planarizing layer 162.

For example, a contact hole may be formed in the first planarizing layer 161 and the connecting electrode 170 may be disposed in the contact hole of the first planarizing layer 161. The second planarizing layer 162 having a contact hole may be disposed on the first planarizing layer 161 and the connecting electrode 170. A first electrode (such as an anode) 310 may be disposed in the contact hole of the second planarizing layer 162. As a result, the thin film transistor 200 and the first electrode 310 may be electrically connected to each other through the connecting electrode 170.

One end portion of the connecting electrode 170 may be connected to the thin film transistor and the other end portion of the connecting electrode 170 may be connected to the first electrode 310.

The connecting electrode 170 may include one of molybdenum (Mo), copper (Cu), titanium (Ti), aluminum (Al), chromium (Cr), gold (Au), nickel (Ni), neodymium (Nd), tungsten (W) and transparent conductive oxide (TCO) or an alloy thereof and may have a single layer or a multiple layer thereof. However, it is not limited thereto.

The connecting electrode 170 may be omitted based on a structure and a type of the LED display device 100.

The first electrode 310 may be disposed on the planarizing layer 160. The first electrode 310 may be disposed in the emitting area EA and a portion of the non-emitting area NEA.

When the LED display device 100 has a top emission type, the first electrode 310 may function as a reflective electrode comprising an opaque conductive material. The first electrode 310 may include one of silver (Ag), aluminum (Al), gold (Au), molybdenum (Mo), tungsten (W) and chromium (Cr) or an alloy thereof. For example, the first electrode 310 may have a triple layer of silver (Ag)/lead (Pb)/copper (Cu), and it is not limited thereto. Alternatively, the first electrode 310 may further include a transparent conductive material having a relatively high work function such as indium tin oxide (ITO).

When the LED display device 100 has a bottom emission type, the first electrode 310 may function as a transparent electrode of a transparent conductive material. The first electrode 310 may include one of indium tin oxide (ITO) and indium zinc oxide (IZO).

A bank 320 may be disposed on the first electrode 310 and the planarizing layer 160.

The bank 320 may divide the plurality of subpixels SP to minimize a light blurring effect or light blurring issue and prevent a color mixture in various viewing angles.

The bank 320 may surround the emitting area EA and the non-emitting area NEA and may be disposed in the non-emitting area NEA.

The bank 320 may have a bank hole BH exposing the first electrode 310 and may have a bank trench BT in the non-emitting area NEA between the adjacent subpixels.

The bank 320 may include at least one of an inorganic insulating material such as silicon nitride (SiNx) and silicon oxide (SiOx), an organic insulating material such as benzocyclobutene (BCB), acrylic resin, epoxy resin, phenolic resin, polyamide resin and polyimide resin, and a photoresist including black pigment, and it is not limited thereto.

The bank 320 may be transparent or may have black or a color. The bank 320 may be disposed to cover an end portion of the first electrode 310.

The bank trench BT may be formed by removing a portion of the bank 320. When the bank 320 is completely removed in a region for the bank trench BT, bank trench BT may expose the planarizing layer 160. Although the bank 320 is completely removed in the region for the bank trench BT in FIG. 3, the bank 320 may be partially removed in another embodiment. The bank 320 in the region for the bank trench BT may have a thickness of one-second to one-third of a thickness of bank 320 in the other region.

The bank trench BT may overlap a first touch electrode 540_R, a first touch connecting electrode 520, a second touch electrode and a second touch connecting electrode 540_C.

A fabrication process of the bank trench BT will be illustrated with reference to FIGS. 4A to 4D.

At least one first spacer 330 may be disposed on the bank 320. The first spacer 330 may include the same material as the bank 320. The first spacer 330 may be formed simultaneously with the bank 320 or may be formed through a different process from the bank 320.

A thickness of the first spacer 330 may be greater than a thickness of the bank 320. For example, the thickness of the first spacer 330 may be within a range of about 1 μm to about 2 μm.

A second spacer 340 may be disposed on the bank 320 and the planarizing layer 160 within the bank trench BT. At least part of the second spacer 340 may be disposed on at least part of the bank 320. Edges of the second spacer 340 may be disposed on respective edges of the bank 320, while a center of the second spacer 340 may not be disposed on the bank 320.

Since an emitting layer 350 or a second electrode 360 is cut by the second spacer 340 in some example embodiments, it is prevented that an electron in the emitting layer 350 moves to the adjacent subpixel. As a result, a lateral leakage current may be minimized due to the second spacer 340 even when a gap distance between the adjacent subpixels is reduced.

The second spacer 340 may be disposed in the bank trench BT or may cover a portion of a sidewall of the bank trench BT.

The second spacer 340 may be a column structure having a reverse taper shape. For example, the second spacer 340 may have an bottom surface 340bs and a top surface 340us (FIG. 4D), and a size of the top surface 340us of the second spacer 340 may be greater than a size of the bottom surface 340bs of the second spacer 340. The reverse taper shape of the second spacer 340 facilitates that the emitting layer 350 and the second electrode 360 each disconnects or includes a disconnect portion or disconnect portions about the second spacer 340. For example, the emitting layer 350 and the second electrode 360 each does not form on the sidewall of the second spacer and does not form on a region of the second planarizing layer 162 that is immediately adjacent to the bottom surface 340bs (FIG. 4D) of the second spacer 340.

The second spacer 340 may include the same material as the bank 320 or the first spacer 330. A fabrication process of the second spacer 340 will be illustrated with reference to FIGS. 4A to 4D.

A thickness of the second spacer 340 may be greater than a thickness of the bank 320.

A second height or vertical distance H2 from the substrate 110 to the second spacer 340 may be smaller than a first height or vertical distance H1 from the substrate 110 to the first spacer 330. Since the second spacer 340 is disposed in the bank trench BT formed by partially removing the bank 320, the height or vertical distance of the top of the second spacer 340 from the substrate 110 may be smaller than the height or vertical distance of the top of the first spacer 330 on the bank 320 from the substrate 110. Height and vertical distance here refer to a direction/orientation perpendicular to a display surface of the display device, i.e. perpendicular to the substrate 110. Alternatively, or in addition, as depicted in FIG. 3, a fourth height H4 of the second spacer 340 may be smaller than a third height H3 of the first spacer 330.

When the second height or vertical distance H2 of the second spacer 340 from the substrate 110 is the same as or similar to the first height or vertical distance H1 of the top of the first spacer 330 from the substrate 110, the second spacer 340 may contact a fine metal mask (FMM) for forming the emitting layer 350 to be distorted or damaged. In the embodiment of the present disclosure, since the second spacer 340 is disposed in the bank trench BT, the first spacer 330 instead of the second spacer 340 contacts the fin metal mask and distortion or damage of the second spacer 340 is prevented.

The second spacer 340 may include at least three spacer patterns. For example, the second spacer may include first, second and third spacer patterns 340a, 340b and 340c.

The first, second and third spacer patterns 340a, 340b and 340c may be disposed to be separated from each other. A spacer pattern hole PH may be disposed between the first, second and third spacer patterns 340a, 340b and 340c. In other words, a first spacer pattern hole PH may be disposed between the first spacer pattern 340a and the second spacer pattern 340b, and a second spacer pattern hole PH may be disposed between the spacer pattern 340b and the third spacer pattern 340c. In some examples, the second spacer 340 may comprise first, second and third spacer patterns, with a first spacer pattern hole PH between the first and second spacer patterns and a second spacer pattern hole PH between the second and third spacer patterns. The second spacer may comprise at least first and second spacer patterns with a spacer pattern hole therebetween. Increasing numbers of spacer patterns and spacer pattern holes may advantageously further reduce the leakage current between subpixels. The second spacer comprising spacer patterns may prevent the emitting layer 350 (and the second electrode 360) from being formed or deposited on side slopes of the second spacer. This is because the spacer patterns form overhangs which means that these side slopes are shaded from deposition from above. This enables the formation of discontinuities/cuts/gaps in the emitting layer 350, thereby reducing leakage current between subpixels.

At least one of the spacer patterns may be disposed to be separated from the bank 320. For example, the spacer pattern 340b of the second spacer 340 may be disposed to be separated from the bank 320. The second spacer pattern 340b may be wider than the first spacer pattern 340a and wider than the third spacer pattern 340c.

At least one of the spacer patterns may be disposed to cover a portion of the bank 320. For example, the first and third spacer patterns 340a and 340c of the second spacer 340 may be disposed to cover a portion of the bank 320.

Although the first and third spacer patterns 340a and 340c of the second spacer 340 cover a portion of the bank 320 in FIG. 3, the second spacer 340 may include a plurality of second spacer patterns 340b separated from the bank 320 in the bank trench BT in another embodiment.

Although the second spacer 340 includes three spacer patterns in FIG. 3, the number of the spacer patterns may be changed according to a design and it is not limited thereto.

An emitting layer 350 may be disposed on the first electrode 310, the bank 320, the first spacer 330, the second spacer 340 and the planarizing layer 160.

Since the emitting layer 350 disconnects or is cut by the second spacer 340 and the second spacer hole PH in the non-emitting area NEA in some example embodiments, it is prevented that an electron in the emitting layer 350 moves to the adjacent subpixel. As a result, a lateral leakage current may be minimized even when a gap distance between the adjacent subpixels is reduced. The emitting layer 350 may not form a continuous layer, but instead may comprise a number of cuts, gaps or discontinuities separating respective portions of the emitting layer 350. This may be due to the second spacer 340 in the bank trench BT. In particular, the emitting layer 350 may comprise a discontinuity between a portion thereof disposed on the bank 320 and a portion thereof disposed on the first spacer pattern 340a, may comprise a discontinuity between a portion thereof disposed on the first spacer pattern 340a and a portion thereof disposed the second spacer pattern 340b (i.e. due to the first spacer pattern hole PH), may comprise a discontinuity between a portion thereof disposed on the second spacer pattern 340b and a portion thereof disposed on the third spacer pattern 340c (i.e. due to the second spacer pattern hole PH), and/or may comprise a discontinuity between a portion thereof disposed on the third spacer pattern 340c and a portion thereof disposed on the bank 320. As used herein, a cut in a layer may refer to a cut through that layer, i.e. a complete cut through that layer, or to a surface cut in that layer, i.e. to a cut partially through that layer (i.e. a reduction in thickness). In some examples, the emitting layer 350 may be reduced in thickness in the region of the second spacer 340. For example, the second spacer 340 may comprise one or more side slopes on which the emitting layer 350 is thinner, patchy or discontinuous. The transmission of leakage current through the emitting area in this region may therefore be reduced. In other words, in the region of the second spacer 340, deposition of the emitting layer 350 may be reduced such that, in use, transmission of leakage current in this region is reduced. In the region of the second spacer 340, the emitting layer 350 may not be continuous or may not be uniform.

A portion of the emitting layer 350 may be disposed on the planarizing layer 160, and a portion of the emitting layer 350 may be disposed in the bank trench BT. A portion of the emitting layer 350 may be disposed between the first, second and third spacer patterns 340a, 340b and 340c of the second spacer 340, i.e. in the spacer pattern hole PH.

The emitting layer 350 may include a plurality of stacks (emitting units). For example, the emitting layer 350 may include first and second stacks 351 and 353 (of FIG. 5) and a charge generating layer 352 (of FIG. 5). A structure of the emitting layer 350 will be illustrated with reference to FIG. 5.

A second electrode (such as cathode) 360 may be disposed on the emitting layer 350.

The second electrode 360 may be cut by the second spacer 340 in the non-emitting area NEA. The second electrode 360 may not form a continuous layer, but instead may comprise a number of cuts, gaps or discontinuities separating respective portions of the second electrode 360 and corresponding to the cuts/gaps/discontinuities of the emitting layer 350.

A portion of the second electrode 360 may be disposed in the bank trench BT, and a portion of the second electrode 360 may be disposed between the first, second and third spacer patterns 340a, 340b and 340c of the second spacer 340, i.e. in the spacer pattern hole PH.

For example, each of the first, second and third spacer patterns 340a, 340b and 340c has a reverse taper shape where a side surface of each spacer pattern 340a, 340b and 340c and a top surface of the planarizing layer 162 make an acute angle. As a result, the emitting layer 350 and the second electrode 360 may be cut between the first, second and third spacer patterns 340a, 340b and 340c, and a residual layer RL having the emitting layer 350 and the second electrode 360 may be disposed on the planarizing layer 162 between the first, second and third spacer patterns 340a, 340b and 340c. In other words, the term ‘residual layer’ RL may be used to refer to the emitting layer 350 and the second electrode 360 which are disposed in the spacer pattern holes PH of the second spacer 340. The portion of the emitting layer 350 comprised in the residual layer RL may be separated from the portions of the emitting layer 350 disposed on the first, second and third spacer patterns 340a, 340b, 340c. The portion of the second electrode 360 comprised in the residual layer RL may be separated from the portions of the second electrode 360 disposed on the first, second and third spacer patterns 340a, 340b, 340c. The portions of the emitting layer 350 disposed on one or more of the spacer patterns 340a, 340b, 340c may be separated from the portions of the emitting layer 350 disposed on the adjacent bank 320. The portions of the second electrode 360 disposed on one or more of the spacer patterns 340a, 340b, 340c may be separated from the portions of the second electrode 360 disposed on the adjacent bank 320.

The second electrode 360 may supply an electron to the emitting layer 350 and may include a conductive material having a relatively low work function.

When the LED display device 100 has a top emission type, the second electrode 360 may function as a transparent electrode comprising a transparent conductive material. The second electrode 360 may include one of indium tin oxide (ITO) and indium zinc oxide (IZO).

Alternatively, the second electrode 360 may include a half transparent conductive material. For example, the second electrode 360 may include at least one of alloys such as lithium fluoride/aluminum (LiF/Al), cesium fluoride/aluminum (CsF/Al), magnesium:silver (Mg:Ag), calcium/silver (Ca/Ag), lithium fluoride/magnesium:silver (LiF/Mg:Ag), lithium fluoride/calcium/silver (LiF/Ca/Ag) and lithium fluoride/calcium:silver (LiF/Ca:Ag).

When the LED display device 100 has a bottom emission type, the second electrode 360 may function as a reflective electrode comprising an opaque conductive material. For example, the second electrode 360 may include one of silver (Ag), aluminum (Al), gold (Au), molybdenum (Mo), tungsten (W) and chromium (Cr) or an alloy thereof.

Although not shown, a capping layer (CPL) may be disposed on the second electrode 360.

The capping layer may protect the second electrode 360 and may improve a light extraction effect of the emitting layer 350. The capping layer may have a single layer or a multiple layer, and it is not limited thereto.

The capping layer may be omitted based on a structure and a type of the LED display device 100.

An encapsulating layer 400 may be disposed on the second electrode 360 or the capping layer. The encapsulating layer 400 may protect the first electrode 310, the emitting layer 350 and the second electrode 360 from a moisture, an oxygen or a particle of an exterior. For example, the encapsulating layer 400 may block penetration of an oxygen and a moisture from an exterior to prevent an oxidation of materials of the first and second electrodes 310 and 360 and the emitting layer 350.

The encapsulating layer 400 may include a transparent material so that a light emitted from the emitting layer 350 can pass through the encapsulating layer 400.

The encapsulating layer 400 may include first, second and third encapsulating layers 410, 420 and 430 for blocking penetration of a moisture or an oxygen. The first, second and third encapsulating layers 410, 420 and 430 may have a sequentially laminated structure.

The first and third encapsulating layers 410 and 430 may include an inorganic material such as silicon nitride (SiNx), silicon oxide (SiOx) and aluminum oxide (AlyOz), and it is not limited thereto. The first and third encapsulating layers 410 and 430 may be formed through a vacuum film formation method such as a chemical vapor deposition (CVD) and an atomic layer deposition (ALD), and it is not limited thereto.

Each of the first and third encapsulating layers 410 and 430 may have a multiple layer including at least two layers. For example, the first encapsulating layer 410 may have a triple layer of silicon oxide (SiOx)/silicon nitride (SiNx)/silicon oxide (SiOx), and it is not limited thereto. Alternatively, the first encapsulating layer 410 may have a quadruple layer of silicon oxide (SiOx)/silicon nitride (SiNx)/silicon oxide (SiOx)/silicon oxide (SiOx), and it is not limited thereto.

The second encapsulating layer 420 may cover a particle generated in a fabrication process. The second encapsulating layer 420 may planarize a surface of the first encapsulating layer 410. For example, the second encapsulating layer 420 may be referred to as a particle cover layer.

The second encapsulating layer 420 may include an organic material of a polymer such as silicon oxycarbide (SiOCz), epoxy, polyimide, polyethylene and acrylate, and it is not limited thereto.

The second encapsulating layer 420 may include a heat curable material capable of being cured by a heat or a photo curable material capable of being cured by a light.

A touch sensing layer 500 may be disposed on the encapsulating layer 400.

The touch sensing layer 500 may include a first touch electrode 540_R, a first touch connecting electrode 520, a second touch electrode and a second touch connecting electrode 540_C.

A portion of the first touch electrode 540_R, the first touch connecting electrode 520, the second touch electrode and the second touch connecting electrode 540_C may be disposed to overlap the second spacer 340 and the bank trench BT.

The first touch electrode 540_R, the first touch connecting electrode 520, the second touch electrode and the second touch connecting electrode 540_C may have a mesh pattern where metal lines each having a relatively narrow width cross each other. The mesh pattern may have a rhombic shape. Alternatively, the mesh pattern may have one of rectangular, pentagonal, hexagonal, circular and elliptical shapes, and it is not limited thereto.

The first touch electrode 540_R, the first touch connecting electrode 520, the second touch electrode and the second touch connecting electrode 540_C may include an opaque conductive material having a relatively low resistance. For example, the first touch electrode 540_R, the first touch connecting electrode 520, the second touch electrode and the second touch connecting electrode 540_C may include one of molybdenum (Mo), copper (Cu), titanium (Ti), aluminum (Al), chromium (Cr), gold (Au), nickel (Ni), neodymium (Nd), tungsten (W) and transparent conductive oxide (TCO) or an alloy thereof and may have a single layer or a multiple layer thereof. However, it is not limited thereto.

For example, the first touch electrode 540_R, the first touch connecting electrode 520, the second touch electrode and the second touch connecting electrode 540_C may have a triple layer of titanium (Ti)/aluminum (Al)/titanium (Ti), and it is not limited thereto.

The first touch electrode 540_R, the first touch connecting electrode 520, the second touch electrode and the second touch connecting electrode 540_C may include the same material as the source electrode 250 and the drain electrode 270.

A touch buffer layer 510 may be disposed on the encapsulating layer 400. The touch buffer layer 510 may block penetration of a solution (developing solution or etching solution) used in a fabrication process for the touch sensing layer 500 or a moisture of an exterior into the emitting layer 350. In addition, due to the touch buffer layer 510, it may be prevented that a plurality of touch sensing metals on the touch buffer layer 510 are cut by an external impact, and an interference signal generated when the touch sensing layer 500 is driven may be blocked.

The touch buffer layer 510 may include at least one of an inorganic insulating material such as silicon nitride (SiNx) and silicon oxide (SiOx) and an organic insulating material such as benzocyclobutene (BCB), acrylic resin, epoxy resin, phenolic resin, polyamide resin and polyimide resin, and it is not limited thereto.

The first touch connecting electrode 520 may be disposed on the touch buffer layer 510.

For example, the first touch connecting electrode 520 may be disposed between the adjacent first touch electrodes 540_R along a first direction (X direction). The first touch connecting electrode 520 may electrically connect the plurality of first touch electrodes 540_R spaced apart from and adjacent to each other along the first direction (X direction), and it is not limited thereto.

The first touch connecting electrode 520 may be disposed to overlap the second touch connecting electrode 540_C connecting the adjacent second touch electrodes along a second direction (Y direction). Since the first touch connecting electrode 520 and the second touch connecting electrode 540_C are disposed as different layers, the first touch connecting electrode 520 and the second touch connecting electrode 540_C may be electrically insulated.

A touch insulating layer 530 may be disposed on the touch buffer layer 510 and the first touch connecting electrode 520.

The touch insulating layer 530 may have a contact hole for electrically connecting the first touch electrode 540_R and the first touch connecting electrode 520.

The touch insulating layer 530 may electrically insulate first touch connecting electrode 520 and the second touch connecting electrode 540_C.

The touch insulating layer 530 may have a single layer or a multiple layer of silicon nitride (SiNx) and silicon oxide (SiOx), and it is not limited thereto.

The first touch electrode 540_R, the second touch electrode and the second touch connecting electrode 540_C may be disposed on the touch insulating layer 530.

The first touch electrode 540_R and the second touch electrode may be disposed to be spaced apart from each other. The plurality of first touch electrodes 540_R may be spaced apart from each other along the first direction (X direction). The adjacent first touch electrodes 540_R along the first direction (X direction) may be connected to the first touch connecting electrode 520 between the first touch electrodes 540_R. For example, the adjacent first touch electrodes 540_R may be connected to the first touch connecting electrode 520 through the contact hole in the touch insulating layer 530.

The adjacent second touch electrodes along the second direction (Y direction) may be connected to each other through the second touch connecting electrode 540_C. The second touch electrode and the second touch connecting electrode 540_C may be formed in the same layer. For example, the second touch connecting electrode 540_C may be disposed in the same layer as the second touch electrode and between the second touch electrodes. The second touch connecting electrodes 540_C may be formed to extend from the second touch electrode.

The first touch electrode 540_R, the second touch electrode and the second touch connecting electrode 540_C may be formed through the same process.

A touch planarizing layer 550 may be disposed on the first touch electrode 540_R, the second touch electrode and the second touch connecting electrode 540_C.

A touch diving circuit may receive a touch sensing signal from the first touch electrode 540_R and may transmit a touch driving signal to the second touch electrode. The touch driving circuit may detect a touch of a user using a mutual capacitance between the first touch electrode 540_R and the second touch electrode. For example, when a touch occurs in the LED display device 100, the capacitance between the first touch electrode 540_R and the second touch electrode may be changed. The touch driving circuit may detect the change in the capacitance to calculate a touch coordinate.

A fabrication process of the bank trench BT and the second spacer 340 will be illustrated hereinafter.

In FIG. 4A, the first electrode 310 is formed in the emitting area EA on the substrate 110 having the thin film transistor 200.

In FIG. 4B, the bank 320 and the first spacer 330 are formed in the non-emitting area NEA of the substrate 110 having the first electrode 310.

The bank 320 may include the bank hole BH exposing the first electrode 310 in the emitting area EA. The bank hole BH may be formed by removing a portion of the bank 320.

At least one first spacer 330 may be disposed on the bank 320.

Although the bank 320 and the first spacer 330 are formed through the same process using a halftone mask in FIG. 4B, the bank 320 and the first spacer 330 may be formed through different processes in another embodiment.

In FIG. 4C, the bank trench BT is formed between the adjacent subpixels. The bank trench BT may be formed by etching a portion of the bank 320. The planarizing layer 160 may be exposed through the bank trench BT.

Although a whole of the bank 320 is removed in a region where the bank trench BT is disposed in FIG. 4C, a portion of the bank 320 may be removed in another embodiment. For example, a portion of the bank 320 may remain on the planarizing layer 160 in the region where the bank trench BT is disposed by removing a portion of the bank 320 instead of a whole of the bank 320.

In FIG. 4D, the second spacer 340 may be formed in the bank trench BT.

The second spacer 340 may include the first, second and third spacer patterns 340a, 340b and 340c. The first, second and third spacer patterns 340a, 340b and 340c may be disposed to be spaced apart from each other. The spacer pattern hole PH may be disposed between the first, second and third spacer patterns 340a, 340b and 340c.

At least one of the first, second and third spacer patterns 340a, 340b and 340c of the second spacer 340 may cover a portion of the bank 320. For example, the first and third spacer patterns 340a and 340c of the second spacer 340 may be disposed to be spaced apart from the bank 320.

Although the bank hole BH, the bank trench BT, the first spacer 330 and the second spacer 340 are formed through the different processes in FIGS. 4A to 4D, the bank hole BH and the bank trench BT may be simultaneously formed and then the first spacer 330 and the second spacer 340 may be simultaneously formed in another embodiment.

FIG. 5 is view showing an emitting layer of a light emitting diode display device according to an embodiment of the present disclosure.

Although the emitting layer includes two stacks (emitting units) and one charge generating layer in FIG. 5, the emitting layer may include three or more stacks and two or more charge generating layers in another embodiment.

In FIG. 5, the emitting layer 350 may include a plurality of stacks (emitting units). For example, the emitting layer 350 may include a first stack 351, a second stack 353 and a charge generating layer 352 between the first and second stacks 351 and 353.

The first electrode (such as anode) 310, the first stack 351, the charge generating layer 352, the second stack 353 and the second electrode (such as cathode) 360 may be sequentially disposed on the substrate 110 having the first, second and third subpixels SP_1, SP_2 and SP_3.

The first stack 351 may include a hole injecting layer 351-A, a first hole transporting layer 351-B, a first emitting material layer 351-C and a first electro transporting layer 351-D.

The second stack 353 may include a second hole transporting layer 353-A, a second emitting material layer 353-B, a second electron transporting layer 353-C and an electron injecting layer 353-D.

The charge generating layer 352 may include a negative (N) type charge generating layer n-CGL assisting injection of an electron to the first stack 351 and a positive (P) type charge generating layer p-CGL assisting injection of a hole to the second stack 353.

Although not shown, an electron blocking layer may be disposed between the first hole injecting layer 351-A and the first emitting material layer 351-C, and a hole blocking layer may be disposed between the first emitting material layer 351-C and the charge generating layer 352. In addition, an electron blocking layer may be disposed between the charge generating layer 352 and the second emitting material layer 353-B, and a hole blocking layer may be disposed between the second emitting material layer 353-B and the electron injecting layer 353-D.

A portion of the layers of the emitting layer 350 may be cut between the adjacent subpixels by the bank trench BT including the second spacer 340 under the emitting layer 350. As a result, it is prevented that an electron in the emitting layer 350 moves to the adjacent subpixel. Specifically, a recognition deterioration between the adjacent subpixels in a relatively low gray level is reduced and a color reproducibility is improved.

The first emitting material layer 351-C and the second emitting material layer 353-B may be disposed to correspond to each subpixel and to be spaced apart from each other. For example, the first emitting material layer 351-C and the second emitting material layer 353-B may be disposed to overlap the bank hole BH and an end portion of the bank 320.

The hole injecting layer 351-A may assist injection of a hole. The hole injecting layer 351-A may include at least one of HATCN (1,4,5,8,9,11-hexaazatriphenylene-hexanitrile), CuPc (cupper phthalocyanine), PEDOT (poly(3,4)-ethylenedioxythiophene), PANI (polyaniline) and NPD (N,N-dinaphthyl-N,N′-diphenylbenzidine), and it is not limited thereto.

The first hole transporting layer 351-B and the second hole transporting layer 353-A may assist transportation of a hole. The first hole transporting layer 351-B and the second hole transporting layer 353-A may include at least one of NPD (N,N-dinaphthyl-N,N′-diphenylbenzidine), TPD (N,N′-bis-(3-mePHylphenyl)-N,N′-bis-(phenyl)-benzidine), s-TAD and MTDATA (4,4′,4″-Tris(N-3-mePHylphenyl-N-phenyl-amino)-triphenylamine), and it is not limited thereto.

The first electron transporting layer 351-D and the second electron transporting layer 353-C may assist transportation of an electron. The first electron transporting layer 351-D and the second electron transporting layer 353-C may include at least one of Alq3 (tris(8-hydroxyquinolino)aluminum), PBD (2-(4-biphenylyl)-5-(4-tert-butylpheny)-1,3,4oxadiazole), TAZ, spiro-PBD, BAlq and SAlq, and it is not limited thereto.

The electron injecting layer 353-D assists injection of an electron. The electron injecting layer may include at least one of 353-D Alq3 (tris(8-hydroxyquinolino)aluminum), PBD (2-(4-biphenylyl)-5-(4-tert-butylpheny)-1,3,4oxadiazole), TAZ, spiro-PBD, BAlq and SAlq, and it is not limited thereto.

The first emitting material layer 351-C and the second emitting material layer 353-B may be disposed in the bank hole BH to overlap a portion of the bank 320 and to be spaced apart from each other between the adjacent subpixels. For example, the first emitting material layer 351-C and the second emitting material layer 353-B may be deposited in each subpixel using a fine metal mask (FMM).

The first emitting material layer 351-C and the second emitting material layer 353-B may overlap each other and may emit a light corresponding to the same color. The first emitting material layer 351-C and the second emitting material layer 353-B may emit a light of the same wavelength, and it is not limited thereto.

The first emitting material layer 351-C and the second emitting material layer 353-B may include emitting materials emitting red, green and blue colored lights, and the emitting materials may be formed using a phosphorescent material or a fluorescent material.

For example, a first red emitting material layer 351R and a second red emitting material layer 353R in the first subpixel SP_1 may be formed of a phosphorescent material including a host material of CBP (carbazole biphenyl) or mCP (1,3-bis(carbazol-9-yl) and a dopant material of one of PIQIr(acac) (bis(1-phenylisoquinoline) acetylacetonate iridium), PQIr(acac) (bis(1-phenylquinoline) acetylacetonate iridium), PQIr (tris(1-phenylquinoline) iridium) and PtOEP (octaethylporphyrin platinum) or may be formed of a fluorescent material including PBD:Eu(DBM)3(Phen) or Perylene. However, it is not limited thereto.

For example, a first green emitting material layer 351G and a second green emitting material layer 353G in the second subpixel SP_2 may formed of a phosphorescent material including a host material of CBP or mCP and a dopant material of Ir complex including Ir(ppy)3(fac tris(2-phenylpyridine) iridium) or may be formed of a fluorescent material including Alq3 (tris(8-hydroxyquinolino)aluminum). However, it is not limited thereto.

For example, a first blue emitting material layer 351B and a second blue emitting material layer 353B in the third subpixel SP_3 may formed of a phosphorescent material including a host material of CBP or mCP and a dopant material of (4,6-F2ppy)2Irpic or may be formed of a fluorescent material including one of spiro-DPVBi, spiro-6P, distyryl benzene (DSB), distyryl arylene (DSA), PFO polymer and PPV polymer. However, it is not limited thereto.

The first emitting material layer 351-C and the second emitting material layer 353-B may include an auxiliary emitting material layer. For example, the auxiliary emitting material layer may be disposed on or under the first emitting material layer 351-C and the second emitting material layer 353-B. The auxiliary emitting material layer may emit a light of the same color as or the different color from the first emitting material layer 351-C and the second emitting material layer 353-B.

The N type charge generating layer n-CGL may be formed of one of an alkali metal, an alkali metal compound, an organic material for injecting an electron and an alloy thereof. For example, the N type charge generating layer n-CGL may have a mixture layer of N type materials such as anthracene derivative doped with lithium (Li) or cesium (Cs), and it is not limited thereto.

The P type charge generating layer p-CGL may be formed of an organic material used for a hole injecting layer. For example, the P type charge generating layer p-CGL may have a single layer of P type materials such as HATCN or F4-TCNQ, and it is not limited thereto.

Each layer of the first stack 351, the second stack 353 and the charge generating layer 352 may have a multiple layer or may be omitted.

Consequently, in the LED display device according to an embodiment of the present disclosure, since the bank trench having at least one second spacer is disposed between the adjacent subpixels, the lateral leakage current increasing as a gap distance between the adjacent subpixels is reduced or blocked.

Since the emitting layer is cut by the bank trench having at least one second spacer between the adjacent subpixels in some example embodiments, it is prevented that the electron in the emitting layer moves to the adjacent subpixel.

Since the lateral leakage current is reduced or blocked between the adjacent subpixels, the recognition deterioration between the adjacent subpixels in a relatively low gray level is reduced and a color reproducibility is improved.

Example embodiments of the present disclosure can also be described as follows:

According to an example embodiment of a present disclosure, a display device may include: a substrate having first and second subpixels each including a respective emitting area and a non-emitting area surrounding the emitting areas; a respective first electrode in each of the first and second subpixels; a bank, the bank having a respective bank hole in the emitting area and a bank trench in the non-emitting area; a first spacer on the bank; a second spacer in the bank trench; an emitting layer on the first electrode and the bank trench and including a plurality of stacks and at least one charge generating layer between the plurality of stacks; and a second electrode on the emitting layer.

In some example embodiments, the second spacer may have a reverse taper shape.

In some example embodiments, a height of a top of the second spacer from the substrate may be different from a height of a top of the first spacer from the substrate.

In some example embodiments, a height of a top of the second spacer from the substrate may be smaller than a height of a top of the first spacer from the substrate.

In some example embodiments, a thickness of the second spacer may be greater than a thickness of the bank.

In some example embodiments, the second spacer may include at least a first spacer pattern and a second spacer pattern with a spacer pattern hole therebetween.

In some example embodiments, the second spacer may include at least a first spacer pattern, a second spacer pattern and a third spacer pattern, with a first spacer pattern hole between the first and second spacer patterns and a second spacer pattern hole between the second and third spacer patterns.

In some example embodiments, at least one of the first, second and third spacer patterns covers a portion of the bank.

In some example embodiments, the display device may further include: a thin film transistor on the substrate; and a planarizing layer on the thin film transistor.

In some example embodiments, the bank trench may expose the planarizing layer.

In some example embodiments, the second spacer may be disposed on the planarizing layer.

In some example embodiments, the emitting layer may be disposed on the planarizing layer.

In some example embodiments, the emitting layer may be cut in the non-emitting area by the second spacer.

In some example embodiments, the at least one charge generating layer may include first and second charge generating layers.

In some example embodiments, each of the plurality of stacks may include an emitting material layer.

In some example embodiments, the display device may further include: an encapsulating layer on the second electrode; and a touch sensing layer on the encapsulating layer.

In some example embodiments, the touch sensing layer may include first and second touch electrodes overlapping the second spacer.

In some example embodiments, a height of the second spacer may be smaller than a height of the first spacer.

According to another example embodiment of the present disclosure, a display device may include: a substrate including a display area having a plurality of subpixels and a non-emitting area between the plurality of subpixels and a non-display area adjacent to the display area; a respective first electrode in each of the plurality of subpixels; a bank dividing the plurality of subpixels; an emitting layer on the first electrode; a second electrode on the emitting layer; and a cut in the emitting layer of/between two adjacent subpixels of the plurality of subpixels.

In some example embodiments, the bank may include a plurality of bank holes corresponding to the plurality of subpixels, respectively, and a bank trench corresponding to the non-emitting area.

In some example embodiments, the display device may further include a first spacer on the bank.

In some example embodiments, the cut may be formed of a spacer patterns 340a, 340b, and 340c, in the bank trench BT.

In some example embodiments, the second spacer may include a same material as the bank.

In some example embodiments, because some of the second spacers 340 (e.g., 340a, 340c) overlaps a portion of the bank, the cutting portion has a dimension in a first direction, e.g., a direction between two adjacent sub-pixels, that is greater than a dimension of the bank trench BT in the first direction.

According to still another example embodiment of the present disclosure, a method for manufacturing a display device may include: forming a plurality of first electrodes spaced apart from each other on a substrate; forming a bank on the substrate on which the plurality of first electrodes are formed; forming a bank hole in the bank so that a portion of each of the plurality of first electrodes is exposed, and forming a bank trench between adjacent first electrodes of the plurality of first electrodes in the bank; forming a second spacer in the bank trench; forming an emission layer on the second spacer and the bank trench, the emission layer including a plurality of stacks and at least one charge generating layer between the plurality of stacks; and forming a second electrode on the emission layer.

In some example embodiments, the method may further include forming a first spacer on the bank simultaneously with the second spacer.

Although the cutting portion is described herein mainly with reference to an example embodiment in which the cutting portion includes a second spacer in the bank trench, the cutting portion may have another form according to actual needs.

It will be apparent to those skilled in the art that various modifications and variation can be made in the present disclosure without departing from the scope of the disclosure. Thus, it is intended that the present disclosure cover the modifications and variations of this disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate having first and second subpixels each including a respective emitting area; and a non-emitting area surrounding the emitting areas;
a respective first electrode in each of the first and second subpixels;
a bank, the bank having a respective bank hole in each of the emitting areas and a bank trench in the non-emitting area;
a first spacer on the bank;
a second spacer in the bank trench;
an emitting layer on the first electrode and the bank trench and including a plurality of stacks and at least one charge generating layer between the plurality of stacks; and
a second electrode on the emitting layer.

2. The display device of claim 1, wherein the second spacer has a reverse taper shape.

3. The display device of claim 1, wherein a height of a top of the second spacer from the substrate is different from a height of a top of the first spacer from the substrate.

4. The display device of claim 1, wherein a height of a top of the second spacer from the substrate is smaller than a height of a top of the first spacer from the substrate.

5. The display device of claim 1, wherein a thickness of the second spacer is greater than a thickness of the bank.

6. The display device of claim 1, wherein the second spacer includes at least a first spacer pattern and a second spacer pattern with a spacer pattern hole therebetween.

7. The display device of claim 1, wherein the second spacer includes at least a first spacer pattern, a second spacer pattern and a third spacer pattern, with a first spacer pattern hole between the first and second spacer patterns and a second spacer pattern hole between the second and third spacer patterns.

8. The display device of claim 7, wherein at least one of the first, second and third spacer patterns covers a portion of the bank.

9. The display device of claim 1, further comprising:
a thin film transistor on the substrate; and
a planarizing layer on the thin film transistor.

10. The display device of claim 9, wherein the bank trench extends to the planarizing layer.

11. The display device of claim 9, wherein the second spacer is disposed on the planarizing layer.

12. The display device of claim 9, wherein the emitting layer is disposed on the planarizing layer.

13. The display device of claim 1, wherein the emitting layer comprises a cut in the non-emitting area by the second spacer.

14. The display device of claim 1, wherein the at least one charge generating layer includes first and second charge generating layers.

15. The display device of claim 1, wherein each of the plurality of stacks includes an emitting material layer.

16. The display device of claim 1, further comprising:
an encapsulating layer on the second electrode; and
a touch sensing layer on the encapsulating layer.

17. The display device of claim 16, wherein the touch sensing layer includes first and second touch electrodes overlapping the second spacer.

18. The display device of claim 1, wherein a height of the second spacer is smaller than a height of the first spacer.

19. A display device, comprising:
a substrate including a display area having a plurality of subpixels and a non-emitting area between the plurality of subpixels and a non-display area adjacent to the display area;
a respective first electrode in each of the plurality of subpixels;
a bank on the non-emitting area and between the plurality of subpixels;
an emitting layer on the first electrodes;
a second electrode on the emitting layer; and
a cut in the emitting layer between two adjacent subpixels of the plurality of subpixels.

20. The display device of claim 19, wherein the bank includes a plurality of bank holes corresponding to the plurality of subpixels, respectively, and a bank trench in the non-emitting area.

21. The display device of claim 19, further comprising a first spacer on the bank.

22. The display device of claim 21, wherein the cut is formed by a second spacer in the bank trench.

23. The display device of claim 22, wherein the second spacer includes a same material as the bank.

24. The display device of claim 22, wherein a height of the second spacer is smaller than a height of the first spacer.
